(19) United States
(12) Patent Application Publication
(10) Pub. No.: US 2012/0039349 A1
(43) Pub. Date: Feb. 16, 2012

(54) CIRCUIT FOR CONTROLLING A GAIN MEDIUM

(76) Inventors: Allen Priest, Escondido, CA (US); David Boyden, Escondido, CA (US)

(21) Appl. No.: 13/211,186

(22) Filed: Aug. 16, 2011

Related U.S. Application Data
(60) Provisional application No. 61/374,228, filed on Aug. 16, 2010.

(51) Int. Cl. H01S 5/06; H01S 3/00

(52) U.S. Cl. 372/38.01; 372/38.07

(57) ABSTRACT

An assembly (10) that generates a laser beam (12) includes a voltage source (14), a gain medium (24A), a closed loop current regulator (22), and a controller (18). The gain medium (24A) generates the laser beam (12) when medium current flows through the gain medium (24A). The current regulator (22) regulates the medium current that flows through gain medium (24A) from the voltage source (14) independent of a voltage of the voltage source (14). The controller (18) directs a command input (20) to the current regulator (22) that is used to control the current regulator (22).

### RELATED INVENTIONS

This application claims priority on U.S. Provisional Application Ser. No. 61/374,228, filed on Aug. 16, 2010, and entitled “DRIVE CIRCUIT FOR CONTROLLING A QUANTUM CASCADE LASER MODULE”. As far as permitted, the contents of U.S. Provisional Application Ser. No. 61/374,228 are incorporated herein by reference.

### BACKGROUND

Mid Infrared (“MIR”) laser sources that produce a fixed wavelength output beam can be used in many fields such as, thermal pointing, medical diagnostics, pollution monitoring, leak detection, analytical instruments, homeland security and industrial process control.

Often, these MIR laser sources include a circuit having a switch which causes the laser to operate in a pulsed fashion. A common, pulsed MIR laser source includes a gain medium, a regulated voltage source, and a switch that selectively directs power from the voltage source to the gain medium. Unfortunately, existing switch designs are not entirely satisfactory because with certain types of gain media, e.g. quantum cascade gain media, can be easily damaged by current spikes.

Moreover, as provided in “Transport and gain in a quantum cascade laser: model and equivalent circuit” written by Khurgin and Dikmelik, Optical Engineering 49(11), 111110 (November 2010), “cascade” type gain media (quantum cascade and interband cascade) present new challenges for achieving functional control because they present a reactive load that is complex compared to traditional gain media such as laser diodes. Thus, in certain conditions, exiting circuit designs do not adequately control a cascade type gain medium.

### SUMMARY

An assembly that generates a laser beam includes a voltage source, a quantum cascade (“QC”) gain medium, a closed loop current regulator, and a controller. The QC gain medium generates a laser beam when medium current flows through the QC gain medium. The current regulator regulates the medium current that flows through the QC gain medium from the voltage source independent of a voltage of the voltage source. The controller directs a command input to the current regulator that is used to control the current regulator.

As an overview, the assembly is uniquely designed so that the current regulator regulates a medium current that flows through the QC gain medium in a closed loop fashion, and this regulation is independent of variations in voltage from the voltage source. Further, in certain embodiments, the current regulator regulates the magnitude of the medium current to be proportional to an amplitude of the command input. Thus, the medium current that is flowing through the laser can be adjusted by adjusting the command input. With this design, the current regulator allows for the individual control of the QC gain medium to account for variations in the QC gain medium and specific adjustment of the laser beam.

In one embodiment, the current regulator includes a transistor that is positioned in series with the QC gain medium, and an amplifier that receives the command input and that controls the transducer. Further, the amplifier can include an amplifier output that is electrically connected to a gate of the transistor, a positive amplifier input that receives the command input, and a negative amplifier input that receives feedback that relates to the medium current.

Additionally, the assembly can include a feedback system that provides feedback that relates to the medium current to the amplifier. In one embodiment, the feedback system includes a first feedback and a second feedback that provide a differential measurement of a feedback voltage across a sense resistor.

In one embodiment, the command input is a pulsed signal having an amplitude that varies over time to selectively pulse the QC gain medium. With this design, the controller can selectively adjust an amplitude, a pulse width and a repetition rate of the command input to control a magnitude, a pulse width and a repetition rate of the laser beam.

The present invention is also directed to a method for generating a laser beam. In this embodiment, the method can include the steps of (i) providing a voltage source; (ii) electrically connecting a QC gain medium to the voltage source, the QC gain medium generating a laser beam when medium current flows through the QC gain medium; (iii) regulating the medium current that flows through QC gain medium with a closed loop current regulator; and (iv) directing a command input to the current regulator that is used to control the current regulator and the medium current.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is a simplified circuit illustration of an assembly having features of the present invention;

FIG. 2 is a simplified graph that illustrates a command input, a medium current, and laser output versus time;

FIG. 3 is a simplified circuit illustration of another embodiment of an assembly having features of the present invention;

FIG. 4 is a simplified circuit illustration of still another embodiment of an assembly having features of the present invention;

FIG. 5 is a simplified circuit illustration of another embodiment of an assembly having features of the present invention; and

FIG. 6 is a simplified circuit illustration of yet another embodiment of an assembly having features of the present invention.

### DESCRIPTION

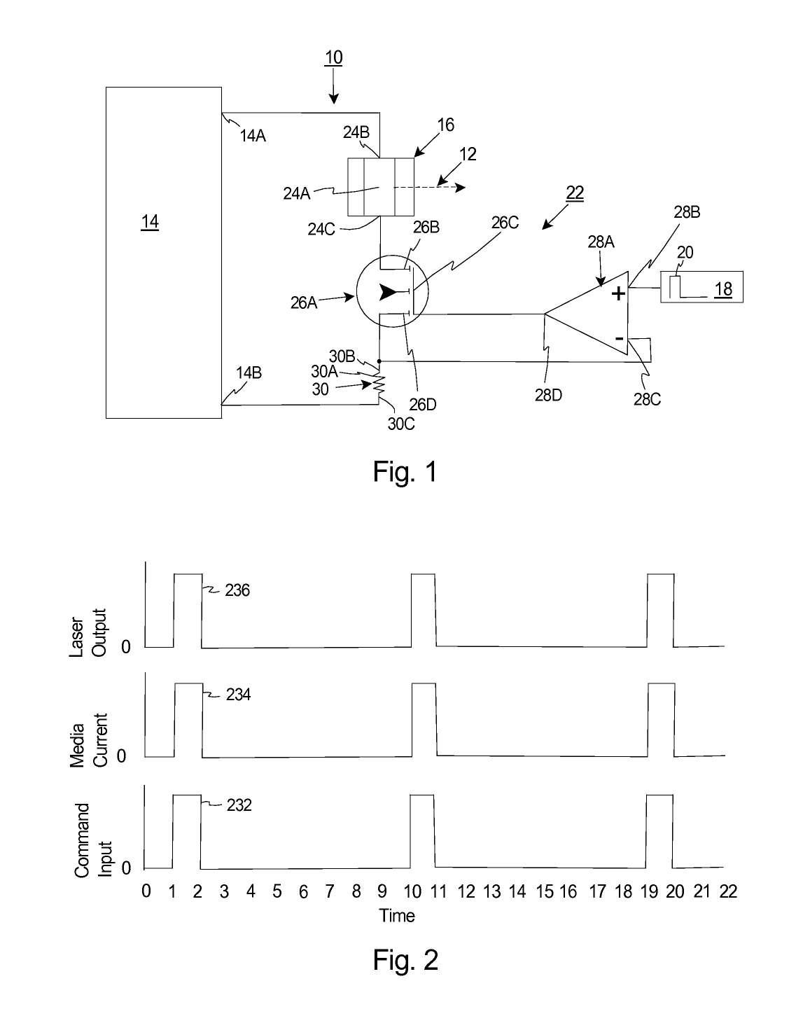

FIG. 1 is a simplified circuit illustration of an assembly 10 that generates a laser beam 12 (illustrated as a dashed arrow). In one embodiment, the assembly 10 includes a voltage source 14, a laser 16, a controller 18 that generates a command input 20, and a current regulator 22. The design of these components can be varied pursuant to the teachings provided herein.

As an overview, the assembly 10 is uniquely designed so that the current regulator 22 is able to regulate a medium current that flows through the laser 16 in a closed loop fashion, and this regulation is independent of variations in voltage from the voltage source 14. This leads to better current regulation, a more accurate output for the laser beam 12, and protection of the laser 16 from damage from current spikes that can result from variations in the voltage source 14.

Further, in certain embodiments, the current regulator 22 is uniquely designed so that the current regulator 22 regulates the medium current to be proportional to an amplitude of the command input 20. Thus, the medium current that is flowing through the laser 16 can be adjusted by adjusting the command input 20. With this design, the current regulator 22 allows for the individual control of the laser 16 to account for variations in the laser 16 and specific adjustment of the laser beam 12.

Moreover, the current regulator 22 provided herein allows for relatively fast on/off switching for precise operation in a pulsed mode, while maintaining the desired current. In certain embodiments, the current regulator 22 provided herein has a relatively high bandwidth to provide the fast on/off switching. For example, in alternative non-exclusive embodiments, the current regulator 22 can have a bandwidth of at least approximately 20, 25, 30, or 35 megahertz for a QC gain medium. However, the desired bandwidth can be varied to achieve the design requirements of the system, including rise times. For example, a rise time of ten nanoseconds can be achieved with 25 megahertz bandwidth.

It should be noted that the circuits provided herein are also relatively insensitive to the transient response of the voltage source 14. Moreover, in certain embodiments, the circuit can be adjusted to compensate for any other transient events that occur within the QC gain medium or in the system.

Additionally, the circuits are designed so that current is regulated during turn-on and turn-off so that current spikes do not occur in the laser 16 due to parasitic inductance or capacitance in the circuit.

Further, with the circuits provided herein, the device can be operated just below threshold and then pulsed above threshold to achieve very fast turn-on of the optical pulse.

There are a number of possible usages for the assembly 10 disclosed herein. In one embodiment, the assembly 10 can be used as part of a thermal pointer (not shown) that generates the laser beam 12 that in is the infrared range, e.g. the mid-infrared range. In this example, the thermal pointer can be used on a weapon (e.g. a gun) in conjunction with a thermal imager to locate, designate, and/or aim at one or more targets.

Alternatively, for example, the assembly 10 can be used for a free space communication system in which the assembly 10 is operated in conjunction with an IR detector located far away, to establish a wireless, directed, invisible data link. Still alternatively, the assembly 10 can be used for any application requiring transmittance of directed infrared radiation through the atmosphere at the distance of thousands of meters, to simulate a thermal source to test IR imaging equipment, as an active illuminator to assist imaging equipment, or any other application. Still alternatively, the assembly 10 can generate an infrared beam 12 that is used in medical diagnostics, pollution monitoring, leak detection, analytical instruments, homeland security and industrial process control.

The voltage source 14 provides a voltage to the laser 16. For example, the voltage source 14 can include one or more batteries (not shown), a generator, or another type of power source. In one embodiment, the voltage source 14 provides DC power. The voltage source 14 can be regulated or unregulated. As provided herein, an adjustable output voltage is not required because the current regulator 22 is used to control the flow through the laser 16. One non-exclusive example of a voltage source 14 provides a voltage of between approximately two and thirty volts. Alternatively, other voltages can be utilized.

In FIG. 1, the voltage source 14 includes a positive terminal 14A and a ground terminal 14B.

The laser 16 is electrically connected to the voltage source 14. In FIG. 1, the laser 16 includes a gain medium 24A having (i) a first connector 24B that is electrically connected to the positive terminal 14A of the voltage source 14, and (ii) a second connector 24C. The gain medium 24A generates the laser beam 12 when the medium current is flowing through the gain medium 24A.

For example, the gain medium 24A can be a Quantum Cascade gain medium that generates a laser beam 12 that is in the mid-infrared range. With this design, electrons transmitted through the QC gain medium 24A emit one photon at each of the energy steps. In the case of a QC gain medium 24A, the “diode” has been replaced by a conduction band quantum well. Electrons are injected into the upper quantum well state and collected from the lower state using a superlattice structure. The upper and lower states are both within the conduction band. Replacing the diode with a single-carrier quantum well system means that the generated photon energy is no longer tied to the material bandgap. This removes the requirement for exotic new materials for each wavelength, and also removes Auger recombination as a problem issue in the active region. The superlattice and quantum well can be designed to provide lasing at almost any photon energy that is sufficiently below the conduction band quantum well barrier. In one, non-exclusive embodiment, the semiconductor QCL laser chip is mounted epitaxial growth side down. A suitable QC gain medium 24A can be purchased from Alpes Lasers, located in Switzerland.

In contrast with typical semiconductor diodes, QC gain media typically exhibit higher capacitance and a higher dynamic resistance. These characteristics can lead to a problem with spikes in current during switching on and off that can damage the QC gain medium. Further, with the quantum cascade gain medium, the active medium relies on intersubband transitions in the quantum wells instead of some naturally occurring atomic or molecular transition. Thus, the reactions in the QC gain medium are much more complicated than in a typical semiconductor laser, and as a result thereof, the QC gain medium is much more difficult to safely control. The circuits provided herein are uniquely designed to accurately control the current to the QC gain medium, while protecting the quantum cascade gain medium from current spikes.

Further, a quantum cascade gain medium is a high current device. Further, the circuits provided herein prevent droop that can occur when a switch initially switches on the high current quantum cascade gain medium.

Moreover, in certain embodiments, the circuits provided herein can provide a faster transition to “ON” because the current can be held just below a threshold which, typically, is at nearly half the operational current (usually chosen near the peak of efficiency). This is possible in part because the QC device has remarkably low Amplified Spontaneous Emission (ASE) compared to laser diodes. As one non-exclusive example, for a QC gain medium, it may be desired to direct one amp of current to the QC gain medium during the ON part of the cycle. With the present design, the circuit can direct less than a threshold current that causes the QC gain medium to generate significant light (e.g. at less than approximately one half amp of current, the QC gain medium does not generate significant light) to the QC gain medium during the OFF part of cycle. This will allow for fast switching between OFF and ON.

Alternatively, in certain embodiments, the gain medium 24A can be an Interband Cascade (“IC”) Lasers. IC gain medium use a conduction-band to valence-band transition as in the traditional diode laser.

As used herein, “cascade type gain medium” shall include both QC gain medium and IC gain medium.

As used herein, the term mid-infrared range has a wavelength in the range of approximately 3-14 microns.

In certain embodiments, the laser 16 can be tuned to adjust the primary wavelength of the laser beam 12. For example, the laser 16 can include a wavelength selective element (not shown) that allows the wavelength of the laser beam 12 to be individually tuned. The design of the wavelength selective element can vary. Non-exclusive examples of suitable wavelength selective elements include a diffraction grating, a MEMS grating, prism pairs, a thin film filter stack with a reflector, an acoustic optic modulator, or an electro-optic modulator. Further, a wavelength selective element can be incorporated into the gain medium 24A. A more complete discussion of these types of wavelength selective elements can be found in the Tunable Laser Handbook, Academic Press, Inc., Copyright 1995, chapter 8, Pages 349-435, Paul Zorabedian, the contents of which are incorporated herein by reference.

Additionally, in certain designs, the laser 16 can be tuned slightly by adjusting the medium current with the controller 16.

As provided herein, the controller 18 is electrically connected to and provides the command input 20 to the current regulator 22 to control the flow of the medium current through the gain medium 24A. Further, the controller 18 can include a processor that can be used to selectively adjust the characteristics of the command input 20 to selectively adjust the medium current and the resulting laser beam 12. For example, the controller 18 can adjust an amplitude, a pulse width and a repetition rate of the command input 20 to control a magnitude, a pulse width and a repetition rate of the laser beam 12. With this design, analog modulation can be achieved by varying the command input 20.

In one embodiment, the controller 18 causes the medium current to be directed to the laser 16 in a pulsed fashion. As a result thereof, the intensity of the laser beam 12 is also pulsed. In one, non-exclusive embodiment, the duty cycle is approximately 12.5 percent. In this embodiment, for example in one cycle, the controller 18 can direct the command input 20 to the current regulator 22 so that medium current flows through the gain medium 24A for approximately 25 milliseconds, and medium current does not flow through the gain medium 24A for approximately 175 milliseconds.

With this design, the QC gain medium 24A lases with little to no heating of the core of the QC gain medium 24A, the average power directed to the QC gain medium 24A is relatively low, and the desired average optical power of the output beam 12 can be efficiently achieved. It should be noted that as the temperature of the QC gain medium 24A increases, the efficiency of the QC gain medium 24A decreases. With this embodiment, the pulsing of the QC gain medium 24A keeps the QC gain medium 24A operating efficiently and the overall system utilizes relatively low power.

Alternatively, the duty cycle can be greater than or less than 12.5 percent. With this design, the controller 18 selectively adjusts a pulse width and a repetition rate of the laser beam 12. Further, the controller 18 can control the magnitude of the medium current (and the laser beam 12) by adjusting the magnitude of a control current of the command input 20.

The current regulator 22 (under the control of the controller 18) regulates the medium current that flows through the gain medium 24A. In FIG. 1, the current regulator 22 provides a fast switching time of the gain medium 24A while maintaining a constant current regulation. Further, because the current regulator 22 regulates the medium current, the current regulator 22 protects the gain medium 24A by inhibiting spikes in the medium current. In this embodiment, the current regulator 22 includes a transistor 26A, an amplifier 28A, and a feedback system 30.

In one embodiment, the transistor 26A includes (i) a source terminal 26B that is electrically connected to the second connector 24C of the gain medium 24A, (ii) a gate 26C that is electrically connected to the amplifier 28A, and (iii) a drain 26C that is electrically connected to the feedback system 30. For example, the transistor 26A can be a field effective transistor. In this embodiment, the transistor 26A is connected in series with the voltage source 14, the gain medium 24A, and the feedback system 30, and the transistor 26A is electrically connected between the gain medium 24A and the feedback system 30.

Alternatively, the transistor 26A can be a bi-polar junction transistor.

The amplifier 28A receives the command input 20 from the controller 18 and controls the gate 26C of the transistor 26A to selectively control the medium current to the gain medium 24A. In FIG. 1, the amplifier 28A includes (i) a positive amplifier input 28B that is electrically connected to the controller 18 and receives the command input 20 from the controller 18, (ii) a negative amplifier input 28C that is electrically connected to and receives feedback from the feedback system 30, and (iii) an amplifier output 28D that is electrically connected to the gate 26C. In one embodiment, the amplifier is an operational amplifier.

As provided herein, the command input 20 is applied to the positive amplifier input 28B. In order to turn off the laser 16, the amplitude of the command input 20 is set to zero volts. When the command input 20 is zero, the amplifier output 28D will turn off the transistor 26A, preventing current from flowing through the gain medium 24A. Alternatively, to turn on the laser 16, the amplitude of command input 20 is increased. This will cause the amplifier output 28D to increase, and the amplifier 28A will drive the gate 26C of the transistor 26A, so that medium current begins to flow through the gain medium 24A and through the feedback system 30.

In one embodiment, the amplifier 28A is designed to control the gate 26C so that a feedback voltage across the feedback system 30 is equal to a command voltage of the command input 20. Stated in another fashion, the operation amplifier 28A is designed to control the gate 26C so that the voltage at the positive amplifier input 28B (the command voltage) is equal to the voltage at the negative amplifier input 28C (the feedback voltage).

The feedback system 30 provides feedback to the amplifier 28A so that the current regulator 22 can precisely control the medium current that flows through the gain medium 24A. In one embodiment, the feedback system 30 includes a sense resistor 30A. In this embodiment, the medium current that flows through the sense resistor 30A creates the feedback voltage that is fed back to the negative amplifier input 28C. From the feedback voltage across the sense resistor 30A, the medium current can be determined.

With the present design, the feedback voltage across the sense resistor 30A is proportional to the medium current, and this feedback voltage is connected back to the negative amplifier input 28C of the amplifier 28A. The amplifier 28A will act to increase the medium current flows through the sense resistor 30A until this feedback voltage is equal to the command voltage of the command input 20. Thus, the magnitude of the medium current flowing through the gain medium 24A will be proportional to the magnitude of the command voltage of the command input 20. Thus, the command input 20 can be adjusted to adjust the medium current.

In FIG. 1, the sense resistor 30A includes a first connector 30B that is electrically connected to the transistor 26A and a second connector 30C that is electrically connected to the ground terminal 14B of the voltage source 14. Further, in this embodiment, the negative amplifier input 28C is electrically connect to the circuit near the first connector 30B of the sense resistor 30A. With this design, the amplifier 28A receives the feedback voltage from near the top of the resistor 30A.

In one embodiment, the current regulator 22 is designed to be very small. Further, the current regulator 22 is placed in close proximity to the laser 16. As a result thereof, any parasitic capacitance and inductance can be minimized allowing for the best performance characteristics for this current regulator 22. The result is improved pulse performance while maintaining strict current regulation. This will, in turn, provide better protection for the laser 16. Further, the current regulator 22 is able to provide shorter pulses with less chance of damaging voltage spikes.

FIG. 2 is a graph that illustrates the command input 232, the medium current 234, and the laser beam output 236 versus time. In this embodiment, the command input 232 is pulsed. As a result thereof, the medium current 234 and the laser beam output 236 are also pulsed. Further, it should be noted that with certain embodiments of the present invention, the circuit is designed so that the medium current 232 is proportional to the command input 232.

It should be noted that the amplitude, the pulse width and the repetition rate of the command input 232 can be selectively controlled to selectively control a magnitude, a pulse width and a repetition rate of the medium current 234 and the output of the laser beam 236.

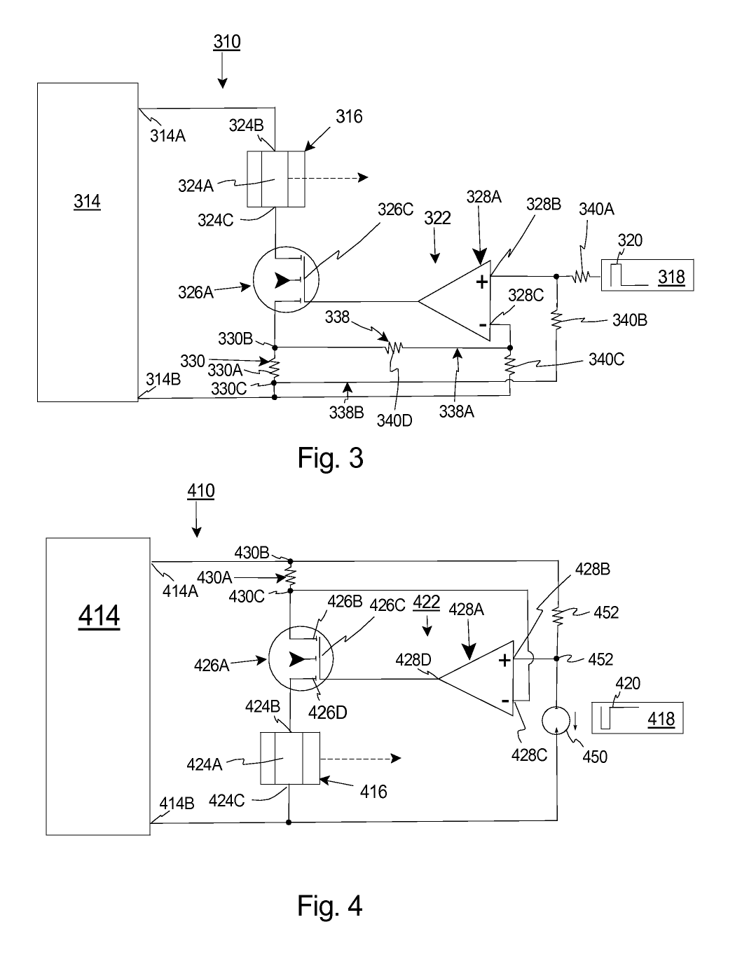

FIG. 3 is a simplified circuit illustration of another embodiment of an assembly 310 that provides fast switching time of the laser 316 device while maintaining a constant current regulation. In this embodiment, the circuit includes the voltage source 314, the laser 316, the current regulator 322, and the controller 318 that are similar to the components described above and illustrated in FIG. 1. In this embodiment, the positive terminal 314A of the voltage source 314 is connected to the first connector 324B of the gain medium 324A, and the second connector 324C of the gain medium 324A is connected in series to the transistor 326A and the sense resistor 330A of the feedback system 330.

Further, in this embodiment, the command input signal 320 from the controller 318 is applied to the positive amplifier input 328B of the amplifier 328A. With this design, in order to turn off the laser 316, the command input 320 is set to zero volts. The operational amplifier 328A output will turn off the transistor 326A, preventing current from flowing. To turn on the laser 316, the command voltage of the command input 320 is increased. The operational amplifier 328A will drive the gate 326C of the transistor 326A, so that current begins to flow through the laser 316 and through the sense resistor 330A. The feedback voltage across sense resistor 330A is proportional to the current flowing and this feedback voltage is connected back to the negative amplifier input 328C of the operational amplifier 328A. The amplifier 328A will act to increase the medium current flow through the sense resistor 330A until this voltage is equal to the command voltage. Thus, the magnitude of the medium current flowing through the laser 316 will be proportional to the amplitude of the command voltage of the command input 320.

However, it should be noted that the circuit illustrated in FIG. 3 differs from the circuit illustrate in FIG. 1 in that the circuit in FIG. 3 includes a different feedback system 330. More specifically, in FIG. 3, the feedback system 330 provides feedback from each side of the sense resistor 330A. This differential measurement of the feedback voltage across the sense resistor 330A reduces and/or cancels out any effects due to parasitic inductance in the power supply connections to the circuit.

In the embodiment illustrated in FIG. 3, the feedback system 330 includes (i) a first feedback 338A that provides the feedback voltage (at the top of the sense resistor 330A near the first connector 330B) across the sense resistor 330A to the negative amplifier input 328C, and (ii) a second feedback 338B that provides the feedback voltage (at the bottom of the sense resistor 330A near the second connector 330C) across the sense resistor 330A to the positive amplifier input 328B.

With the design illustrated in FIG. 3, the feedback system 330 includes a resistor network having (i) a first resistor 340A electrically positioned between the controller 418 and a junction with the second feedback 338B; (ii) a second resistor 340B electrically positioned between the junction of the positive amplifier input 428B and the second connector 330C of the shunt resistor 330A; (iii) a third resistor 340C electrically positioned between the negative amplifier input 428C and the ground terminal 314B of the voltage source 314; and (iv) a fourth resistor 340D electrically positioned between the negative amplifier input 328C and the first connector 330B of the shunt resistor 330A. With this design, the resistor network is used for scaling.

By designing this circuit to be very small, and placing it in close proximity to the QC gain medium 324A, parasitic capacitance and inductance can be minimized allowing for the best performance characteristics for this current regulator 322. The result is improved pulse performance while maintaining strict current regulation. This will, in turn, provide better protection for the QC gain medium 324A.

FIG. 4 is a simplified circuit illustration of another embodiment of an assembly 410 that provides fast switching time of the laser 416 device while maintaining a constant current regulation. In this embodiment, the circuit includes the voltage source 414, the laser 416, the current regulator 422, and the controller 418 that are somewhat similar to the components described above and illustrated in FIG. 3. However, in this embodiment, the position of the current regulator 422 and the laser 416 are switched.

More specifically, in this embodiment, (i) the positive terminal 414A of the voltage source 414 is electrically connected to the first connector 430B of the sense resistor 430A, (ii) the second connector 430C of the sense resistor 430A is electrically connected to the source terminal 426B of the transistor 426A, (iii) the drain 426D of the transistor 426A is electrically connected to the first connector 424B of the gain medium 424A, and (iv) the second connector 424C of the gain medium 424A to the ground terminal 414B of the voltage source 414. With this design, the gain medium 424A is connected between the ground terminal 414B and the transistor 426A, and the sense resistor 430A is connected between the voltage source 414 and the transistor 426A

In this embodiment, the transistor 426A is a P-type MOSFET. Further, in this embodiment, the assembly 410 includes a programmable current source 450 that is connected in parallel with the laser 416. In this embodiment, the controller 418 provides a negative command input into the programmable current source 450 which pulls current from the voltage source 414 through a resistor 452 that is in series with the programmable current source 450 and positioned electrically between the voltage source 414 and the programmable current source 450. The positive amplifier input 428B is electrically connected at a junction 454 electrically positioned between the resistor 452 and the current source 450. This causes a reduction of the voltage on the non-inverting positive amplifier input 428B. The amplifier 428A responds by reducing the voltage from the amplifier output 428D applied to the gate 426C of the transistor 426A, turning it on and allowing current to flow through the sense resistor 430A, and the gain medium 424A.

Moreover, in this embodiment, the negative amplifier input 428C receives feedback from the sense resistor 430A so that the system is a closed loop current regulator 422.

A benefit of this type of circuit is that the second connector 424C of the gain medium 424 is connected to ground potential, e.g. the ground terminal 414B. Typically, this would be the connection which is connected to the heat sink of the device. Because the heat sink is, thus, connected to ground potential, device operation is safer and less prone to damage of the gain medium 424 by accidentally short circuiting the heat sink to ground.

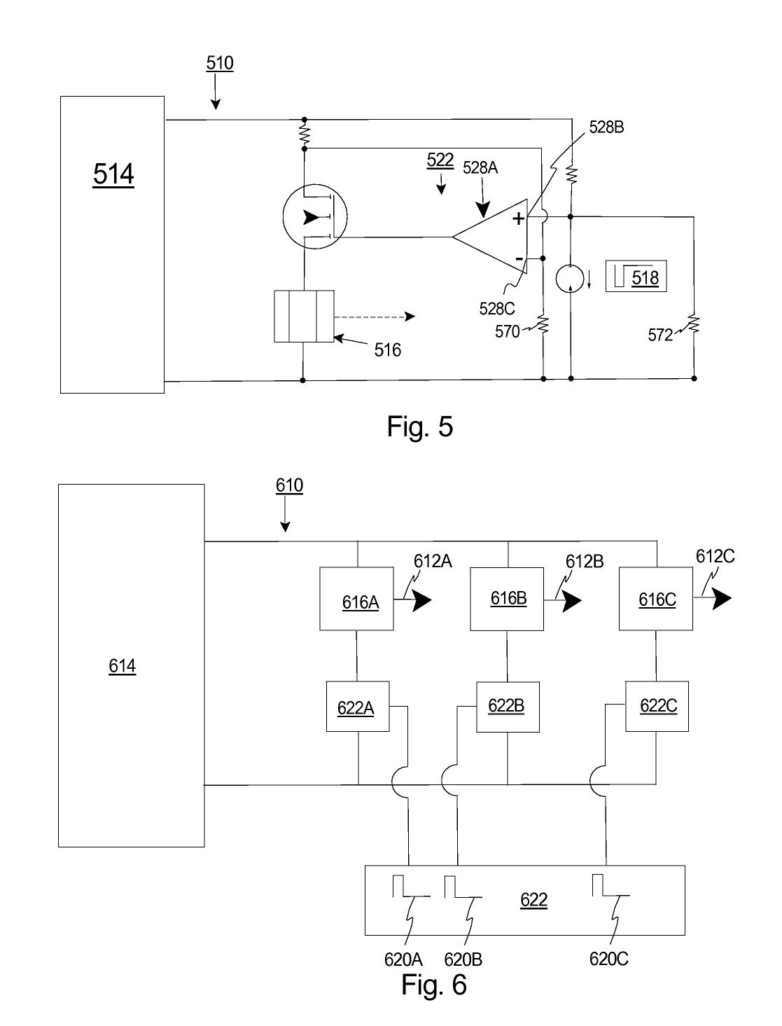

FIG. 5 is a simplified circuit illustration of yet another embodiment of an assembly 510 that provides fast switching time of the laser 516 device while maintaining a constant current regulation. In this embodiment, the circuit includes the voltage source 514, the laser 516, the current regulator 522, and the controller 518 that are somewhat similar to the components described above and illustrated in FIG. 4. However, in this embodiment, the circuit includes two additional resistors 570, 572 that lower the common mode voltage on the amplifier inputs 528B, 528C. More specifically, the resistor 570 is in series with the negative amplifier input 528C, and the resistor 572 is in series with the positive amplifier input 528B. With this design, the common mode voltage on the inputs 528B, 528C are shifted downward so the amplifier 528A is compatible with the voltage source 514. Stated in another fashion, with this design, the common mode voltage is lower to be within the operating range of amplifier 528A. In one embodiment, the resistors 570, 572 have approximately the same resistance.

FIG. 6 is a simplified circuit illustration of yet another embodiment of an assembly 610 having features of the present invention. In this embodiment, the assembly 610 includes the voltage source 614, multiple lasers 616A, 616B, 616C, multiple current regulators 622A, 622B, 622C, and the controller 618. The number of lasers 616A, 616B, 616C in the assembly 610 can be varied. In FIG. 6, the assembly 610 includes three lasers 616A, 616B, 616C. Alternatively, the assembly 610 can include more than three or fewer than three lasers 616A, 616B, 616C.

More specifically, in FIG. 6, the assembly 610 includes (i) a first laser 616A that generates a first beam 612A, (ii) a first current regulator 622A that is in series with the first laser 616A and that regulates the current in the first laser 616A, (iii) a second laser 616B that generates a second beam 612B, the second laser 616B being in parallel with the first laser 616A, (iv) a second current regulator 622B that is in series with the second laser 616B and that regulates the current in the second laser 616B, (v) a third laser 616C that generates a third beam 612C, the third laser 616C being in parallel with the first laser 616A and the second laser 616B, and (vi) a third current regulator 622C that is in series with the third laser 616C and that regulates the current in the third laser 616C.

In this embodiment, the beams 612A, 612B, 612C can be combined to generate a combined output beam. For example, the beams 612A, 612B, 612C can be redirected to be parallel to each other (e.g. travel along parallel axes), and/or fully overlapping, partly overlapping, or are adjacent to each other.

Moreover, in one embodiment, the controller 618 independently directs (i) a first command input 620A to the first current regulator 622A to selectively control the current through the first laser 616A, (ii) a second command input 620B to the second current regulator 622B to selectively control the current through the second laser 616B, and (iii) a third command input 620C to the third current regulator 622C to selectively control the current through the third laser 616C. It should be noted that the controller 618 can be used to control the command inputs 620A, 620B, 620C so that all of the command inputs 620A, 620B, 620C are the same or different. With this design, a common voltage source 614 can be used to save space, while still allowing for the individual control of the lasers 616A, 616B, 616C via individual control of the command inputs 620A, 620B, 620C to account for variations in the lasers 616A, 616B, 616C, and specific adjustment of the individual laser beams 612A, 612B, 612C. As a result thereof, the current through each laser 616A, 616B, 616C can be controlled to be the same or different.

Further, with this design, the controller 618 can simultaneous direct pulses of power to each of the lasers 616A, 616B, 616C so that each of the lasers 612A, 612B, 612C generates the respective beam at the same time. Alternatively, the controller 618 can direct pulses of power to one or more of the lasers 616A, 616B, 616C at different times so that the laser 616A, 616B, 616C generate the respective beam at different times.

It should be noted that the design of the current regulators 622A, 622B, 622C and the relative position of the components of the assembly 610 can be similar to that illustrated in FIG. 1, 3, 4, or 5 and described above.

Finally, the designs provided herein are merely non-exclusive examples of possible designs. While the particular assembly as shown and disclosed herein is fully capable of obtaining the objects and providing the advantages herein before stated, it is to be understood that it is merely illustrative of the presently preferred embodiments of the invention and that no limitations are intended to the details of construction or design herein shown other than as described in the appended claims.

What is claimed is:

1. An assembly that generates a laser beam, the assembly comprising:
a voltage source;
a first QC gain medium that generates the laser beam when medium current flows through the first gain medium;
a closed loop first current regulator that regulates the medium current that flows through first gain medium from the voltage source independent of a voltage of the voltage source; and
a controller that directs a first command input to the first current regulator that is used to control the first current regulator.

2. The assembly of claim 1 further comprising (i) a second QC gain medium that generates the laser beam when medium current flows through the second gain medium; and (ii) a closed loop second current regulator that regulates the medium current that flows through second gain medium from the voltage source independent of the voltage of the voltage source; and wherein the controller independently that directs a second command input to the second current regulator that is used to control the second current regulator.

3. The assembly of claim 1 wherein the first current regulator includes a transistor that is positioned in series with the first QC gain medium, and an amplifier that receives the command input and that controls the transducer.

4. The assembly of claim 3 wherein the amplifier includes an amplifier output that is electrically connected to a gate of the transistor, a positive amplifier input that receives the command input, and a negative amplifier input that receives feedback that relates to the medium current.

5. The assembly of claim 4 further comprising a feedback system that provides feedback that relates to the medium current to the amplifier.

6. The assembly of claim 5 wherein the feedback system includes a first feedback and a second feedback that provide a differential measurement of a feedback voltage across a sense resistor.

7. The assembly of claim 4 wherein the transistor is a field effective transistor, and wherein the amplifier is an operational amplifier.

8. The assembly of claim 1 wherein the first current regulator is designed so that a magnitude of the medium current is proportional to an amplitude of the command input.

9. The assembly of claim 8 wherein the controller selectively adjusts the command input to selectively adjust the medium current.

10. The assembly of claim 1 wherein the command input is a pulsed signal having an amplitude that varies over time to selectively pulse the gain medium.

11. The assembly of claim 1 wherein the controller selectively adjusts an amplitude, a pulse width and a repetition rate of the first command input to control a magnitude, a pulse width and a repetition rate of the laser beam.

12. A method for generating a laser beam, the method comprising the steps of:
providing a voltage source;
electrically connecting a QC gain medium to the voltage source, the gain medium generating the laser beam when medium current flows through the gain medium;
regulating the medium current that flows through gain medium with a closed loop current regulator; and
directing a command input to the current regulator that is used to control the current regulator and the medium current.

13. The method of claim 12 wherein the step of regulating includes the steps of connecting a transistor in series with the QC gain medium, and connecting an amplifier that receives the command input to the transducer.

14. The method of claim 13 further comprising the step of providing feedback that relates to the medium current to the amplifier.

15. The method of claim 13 further comprising the steps of providing a first feedback to the amplifier, and providing a second feedback to the amplifier, the two feedbacks providing a differential measurement of a feedback voltage across a sense resistor.

16. The method of claim 12 wherein the step of directing includes the step of selectively directing the command input to selectively adjust the medium current.

17. The method of claim 12 wherein the command input is a pulsed signal having an amplitude that varies over time to selectively pulse the gain medium.

18. An assembly that generates a laser beam, the assembly comprising:
a voltage source;
a cascade gain medium that generates the laser beam when medium current flows through the gain medium;
a closed loop current regulator that regulates the medium current that flows through the cascade gain medium from the voltage source independent of a voltage of the voltage source, the current regulator including (i) a field effective transistor including a gate, (ii) an operation amplifier that control the operation of the gate, the operational amplifier including a positive amplifier input and a negative amplifier input, and (iii) a feedback system that provides feedback to the negative amplifier input; wherein, the voltage source, the gain medium, the transistor, and the sense resistor are connected in series; and
a controller that directs a command input to the positive amplifier input that is used to control the gate of the transistor.

19. The assembly of claim 18 wherein the feedback system provides feedback to the positive amplifier input.

20. The assembly of claim 18 wherein the command input is a pulsed signal having an amplitude that varies over time to selectively pulse the gain medium.
